(19) United States
(12) Patent Application Publication
(10) Pub. No.: US 2025/0143070 A1
(43) Pub. Date: May 1, 2025

(54) DISPLAY PANEL AND DISPLAY DEVICE

(71) Applicant: KUNSHAN GO-VISIONOX OPTO-ELECTRONICS CO., LTD., Kunshan (CN)

(72) Inventor: Zhimin YAN, Kunshan (CN)

(73) Assignee: KUNSHAN GO-VISIONOX OPTO-ELECTRONICS CO., LTD., Kunshan (CN)

(21) Appl. No.: 19/008,661

(22) Filed: Jan. 3, 2025

Related U.S. Application Data
(63) Continuation of application No. PCT/CN2022/126248, filed on Oct. 19, 2022.

(30) Foreign Application Priority Data
Aug. 19, 2022 (CN) 202211001559.7

(51) Int. Cl. H10K 50/17; H10K 50/13; H10K 50/19

(52) U.S. Cl. CPC H10K 50/171; H10K 50/131; H10K 50/19

(57) ABSTRACT

The present application discloses a display panel and a display device. The display panel includes at least two light-emitting layers stacked in a thickness direction of the display panel. A charge generation layer is provided between two adjacent light-emitting layers, and includes a first charge generation part and a second charge generation part. In a direction perpendicular to the thickness direction of the display panel, each light-emitting layer includes a first light-emitting part and a second light-emitting part spaced apart from each other. In the thickness direction of the display panel, an orthographic projection of the first charge generation part on the light-emitting layer covers the first light-emitting part, an orthographic projection of the second charge generation part on the light-emitting layer covers the second light-emitting part, and the first charge generation part has a thickness greater than a thickness of the second charge generation part.

### CROSS-REFERENCE TO RELATED APPLICATIONS

The present application is a continuation application of International Application No. PCT/CN2022/126248, filed on Oct. 19, 2022, which claims priority to Chinese Patent Application No. 202211001559.7, filed on Aug. 19, 2022, all of which are hereby incorporated by reference in their entireties.

### TECHNICAL FIELD

The present application relates to the technical field of electronic products, and in particular to a display panel and a display device.

### BACKGROUND ART

With the progress of science and technology, digital display devices such as smart phones and tablet computers are widely used, and display panels are indispensable human-computer communication interfaces of these display devices. For example, an organic light emitting diode (OLED) display panel has the advantages of self-luminescence, energy saving and consumption reduction, being bendable, and good flexibility, etc. Moreover, this display panel for realizing display does not need a backlight source and has the characteristics of fast response and good display effect, which has attracted the attention of users and is widely used in end products such as smart phones and tablet computers.

Organic light-emitting devices of the OLED display panel may be divided into the type of single-layer structure and the type of stacked structure. The stacked structure has higher brightness and longer service life compared with the single-layer structure, and thus has high application potential in fields such as TV sets and vehicle-mounted displays. However, an organic light-emitting device having the stacked-layer structure in related art is likely to cause color mixture in the display panel.

Therefore, there is an urgent need for a new display panel and display device.

### SUMMARY OF THE INVENTION

Embodiments of the present application provide a display panel and a display device. A thickness of a first charge generation part is greater than a thickness of a second charge generation part such that a turn-on voltage of a second light-emitting part corresponding to the second charge generation part is increased relatively, thereby reducing the difference between the turn-on voltage of the second light-emitting part and a driving voltage of a first light-emitting part, and avoiding the problem of color mixture in which the second light-emitting part is turned on at the same time as the first light-emitting part is turned on.

In a first aspect, an embodiment of the present application provides a display panel, including: at least two light-emitting layers stacked in a thickness direction of the display panel, where a charge generation layer is provided between two adjacent light-emitting layers, and includes a first charge generation part and a second charge generation part; and in a direction perpendicular to the thickness direction of the display panel, each light-emitting layer includes a first light-emitting part and a second light-emitting part spaced apart from each other, and in the thickness direction of the display panel, an orthographic projection of the first charge generation part on the light-emitting layer covers the first light-emitting part, an orthographic projection of the second charge generation part on the light-emitting layer covers the second light-emitting part, and the first charge generation part has a thickness greater than a thickness of the second charge generation part.

In some embodiments of the first aspect of the present application, each of the first charge generation part and the second charge generation part of the charge generation layer includes a P-type charge generation layer and an N-type charge generation layer stacked in the thickness direction of the display panel; and at least the P-type charge generation layer of the first charge generation part has a thickness greater than the thickness of the P-type charge generation layer of the second charge generation part. In this way, the turn-on voltage of the second light-emitting part is increased relatively.

In some embodiments of the first aspect of the present application, the thickness of the P-type charge generation layer of the first charge generation part ranges from 3 to 20 nm; and/or, the thickness of the P-type charge generation layer of the second charge generation part ranges from 1 to 3 nm. In this way, the effect of increasing the turn-on voltage of the second light-emitting part is ensured.

In some embodiments of the first aspect of the present application, the display panel further includes an organic layer, where the organic layer is disposed between the P-type charge generation layer and the N-type charge generation layer; and in the thickness direction of the display panel, an orthographic projection of the organic layer on the charge generation layer covers an orthographic projection of the first light-emitting part on the charge generation layer; and/or, in the thickness direction of the display panel, the orthographic projection of the organic layer on the charge generation layer covers an orthographic projection of the second light-emitting part on the charge generation layer. In this way, the driving voltage of the first light-emitting part and/or the second light-emitting part is reduced.

In some embodiments of the first aspect of the present application, the organic layer is made of the same material as one of the P-type charge generation layer and the N-type charge generation layer. In this way, production costs are reduced.

In some embodiments of the first aspect of the present application, in the thickness direction of the display panel, the organic layers has a thickness less than or equal to the thickness of each of the P-type charge generation layer and the N-type charge generation layer; and preferably, the thickness of the organic layer ranges from 1 to 2 nm. In this way, the thickness requirements of the display panel are ensured.

In some embodiments of the first aspect of the present application, a material of the organic layer includes at least one of a phenyl-containing compound, a carbazole-containing compound, a triazine-containing compound, and a phenanthroline-containing compound. In this way, the function of reducing the driving voltage of the first light-emitting part and/or the second light-emitting part is achieved.

In some embodiments of the first aspect of the present application, the light-emitting layer further includes a third light-emitting part disposed adjacent to the first light-emitting part, the charge generation layer further includes a third charge generation part, and in the thickness direction of the display panel, an orthographic projection of the third charge generation part on the light-emitting layer covers the third light-emitting part, and the thickness of the first charge generation part is greater than a thickness of the third charge generation part; and preferably, the thickness of the third charge generation part is equal to the thickness of the second charge generation part. In this way, the situation in which the third light-emitting part is turned on at the same time as the first light-emitting part is turned on is avoided.

In some embodiments of the first aspect of the present application, the first light-emitting part, the second light-emitting part, and the third light-emitting part are one of a red light-emitting part, a green light-emitting part, and a blue light-emitting part, respectively; and preferably, the first light-emitting part is the blue light-emitting part, and the second light-emitting part and the third light-emitting part are one of the red light-emitting part and the green light-emitting part, respectively. In this way, the situation in which the red light-emitting part and the green light-emitting part are turned on at the same time as the blue light-emitting part is turned on is avoided.

In a second aspect, the present application provides a display device, including a display panel in any one of the above embodiments.

Compared to the prior art, the display panel provided in the embodiment of the present application includes the light-emitting layers and the charge generation layer, and each light-emitting layer includes the first light-emitting part and the second light-emitting part spaced apart from each other. The first light-emitting part and the second light-emitting part share one charge generation layer, the orthographic projection of the first charge generation part on the light-emitting layer covers the first light-emitting part, that is, the first charge generation part is used for correspondingly generating electrons and holes for the first light-emitting part, and the orthographic projection of the second charge generation part on the light-emitting layer covers the second light-emitting part, that is, the second charge generation part is used for correspondingly generating electrons and holes for the second light-emitting part. It has been found through research that the turn-on voltage of the second light-emitting part is increased relatively by reducing the thickness of the second charge generation part and/or increasing the thickness of the first charge generation part. In this embodiment, the thickness of the first charge generation part is greater than the thickness of the second charge generation part such that the turn-on voltage of the second light-emitting part corresponding to the second charge generation part is increased relatively, thereby reducing the difference between the turn-on voltage of the second light-emitting part and the driving voltage of the first light-emitting part, preventing current crosstalk between the first light-emitting part and the second light-emitting part, and avoiding the problem of color mixture in which the second light-emitting part is turned on at the same time as the first light-emitting part is turned on.

### BRIEF DESCRIPTION OF THE DRAWINGS

FIG. 1 is a diagram of a film layer structure of a display panel according to an embodiment of the present application;

FIG. 2 is a diagram of a film layer structure of a display panel according to another embodiment of the present application;

FIG. 3 is a diagram of a film layer structure of a display panel according to yet another embodiment of the present application;

FIG. 4 is a diagram of a film layer structure of a display panel according to yet another embodiment of the present application;

FIG. 5 is a diagram of a film layer structure of a display panel according to yet another embodiment of the present application;

FIG. 6 is a diagram of a film layer structure of a display panel according to yet another embodiment of the present application;

FIG. 7 is a diagram of a film layer structure of a display panel according to yet another embodiment of the present application;

FIG. 8 is a diagram of a film layer structure of a display panel according to yet another embodiment of the present application;

FIG. 9 is a diagram of a film layer structure of a display panel according to yet another embodiment of the present application; and

FIG. 10 is a diagram of a film layer structure of a display panel according to yet another embodiment of the present application.

### DETAILED DESCRIPTION OF EMBODIMENTS

Features and exemplary embodiments of various aspects of the present application will be described in detail below. In order to make the purposes, technical solutions and advantages of the present application clearer, the present application is further illustrated in detail below in conjunction with the accompanying drawings and specific embodiments. It should be understood that the specific embodiments described herein are merely configured to explain the present application and are not configured to limit the present application. For a person skilled in the art, the present application can be implemented without some of these specific details. The following descriptions of the embodiments are merely to provide a better understanding for the present application by showing examples of the present application.

It would have been obvious for a person skilled in the art that various modifications and variations can be made in the present application without departing from the spirit or scope of the present application. Therefore, the present application is intended to cover modifications and variations of the present application that fall within the scope of the corresponding claims (claimed technical solutions) and their equivalents. It should be noted that implementations provided in the embodiments of the present application may be combined with each other without contradiction.

In related art, an OLED device uses a charge generation layer to connect two light-emitting units, and the charge generation layer tends to have a high mobility, which is likely to result in migration of carriers to adjacent pixels through the charge generation layer, resulting in “color mixture” on a screen. The light-emitting units each have a driving voltage and a turn-on voltage. The driving voltage may be understood as a voltage when the light-emitting unit works normally, and the turn-on voltage is a voltage when the brightness of the light-emitting unit reaches 1 nit. It has been found through research that when the difference between the driving voltage of one of the adjacent light-emitting units and the turn-on voltage of the other one is too large, the threshold of the charge generation layer itself blocking the cross flow of carriers is breached, and the adjacent light-emitting units will be turned on at the same time, which results in the problem of color mixture.

In order to solve the above problem, embodiments of the present application provide a display panel and a display device. A thickness of a first charge generation part is greater than a thickness of a second charge generation part, that is, the thickness of the second charge generation part is reduced and/or the thickness of the first charge generation part is increased, such that a turn-on voltage of a second light-emitting part is increased relatively, thereby reducing the difference between the turn-on voltage of the second light-emitting part and a driving voltage of a first light-emitting part, and avoiding the problem of color mixture in which the second light-emitting part is turned on at the same time as the first light-emitting part is turned on.

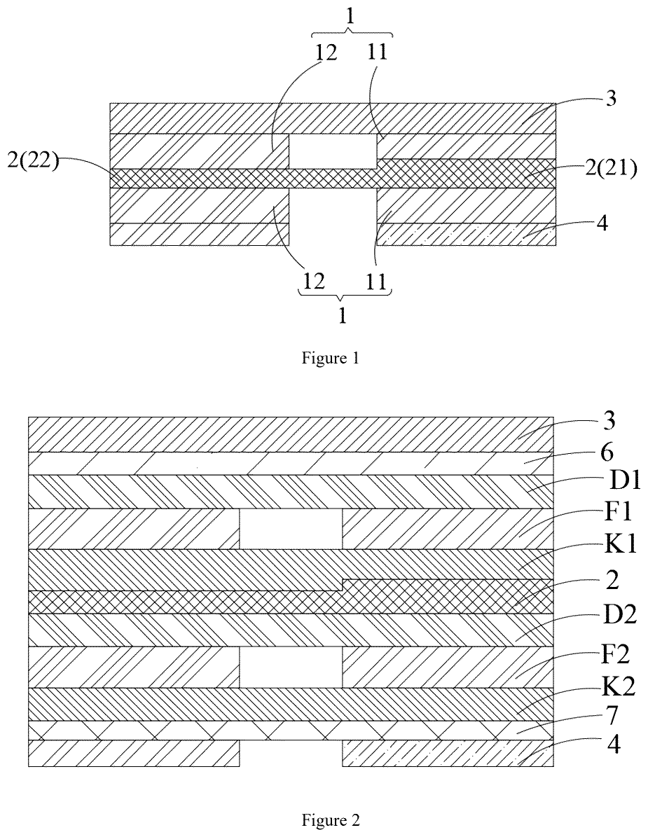

Embodiments of the present application provide a display panel and a display device. Various embodiments of the display panel and the display device will be specifically described below with reference to FIGS. 1 to 10.

Referring to FIGS. 1 to 2, an embodiment of the present application provides a display panel, including: at least two light-emitting layers 1 stacked in a thickness direction of the display panel, where a charge generation layer 2 is provided between two adjacent light-emitting layers 1, and includes a first charge generation part 21 and a second charge generation part 22; and in a direction perpendicular to the thickness direction of the display panel, each light-emitting layer 1 includes a first light-emitting part 11 and a second light-emitting part 12 spaced apart from each other, and in the thickness direction of the display panel, an orthographic projection of the first charge generation part 21 on the light-emitting layer 1 covers the first light-emitting part 11, an orthographic projection of the second charge generation part 22 on the light-emitting layer 1 covers the second light-emitting part 12, and the first charge generation part 21 has a thickness greater than a thickness of the second charge generation part 22.

The display panel provided in the embodiment of the present application includes the light-emitting layers 1 and the charge generation layer 2, and each light-emitting layer 1 includes the first light-emitting part 11 and the second light-emitting part 12 spaced apart from each other. The first light-emitting part 11 and the second light-emitting part 12 share one charge generation layer 2, the orthographic projection of the first charge generation part 21 on the light-emitting layer 1 covers the first light-emitting part 11, that is, the first charge generation part 21 is used for correspondingly generating electrons and holes for the first light-emitting part 11, and the orthographic projection of the second charge generation part 22 on the light-emitting layer 1 covers the second light-emitting part 1, that is, the second charge generation part 22 is used for correspondingly generating electrons and holes for the second light-emitting part 12. It has been found through research that a turn-on voltage of the second light-emitting part 12 is increased relatively by reducing the thickness of the second charge generation part 22 and/or increasing the thickness of the first charge generation part 21. In this embodiment, the thickness of the first charge generation part 21 is greater than the thickness of the second charge generation part 22 such that the turn-on voltage of the second light-emitting part 12 corresponding to the second charge generation part 22 is increased, thereby reducing the difference between the turn-on voltage of the second light-emitting part 12 and a driving voltage of the first light-emitting part 11, preventing current crosstalk between the first light-emitting part 11 and the second light-emitting part 12, and avoiding the problem of color mixture in which the second light-emitting part 12 is turned on at the same time as the first light-emitting part 11 is turned on.

It should be understood that the turn-on voltage of the second light-emitting part 12 may be increased relatively by both reducing the thickness of the second charge generation part 22 and increasing the thickness of the first charge generation part 21.

Optionally, as shown in FIG. 2, the display panel includes two light-emitting layers 1, i.e., a first light-emitting layer F1 and a second light-emitting layer F2. The display panel includes a cathode 3, an electron-injection layer 6, a first electron transport layer D1, the first light-emitting layer F1, a first hole transport layer K1, a charge generation layer 2, a second electron transport layer D2, the second light-emitting layer F2, a second hole transport layer K2, a hole-injection layer 7 and an anode 4 that are stacked. It should be understood that FIGS. 1 and 3 to 10 schematically illustrate only a part of a film layer structure of a display panel.

The light-emitting principle of the OLED display panel is that the light-emitting layer 1 is driven by an applied electric field to emit light through the injection and recombination of carriers from the anode 4 and the cathode 3. The above-mentioned carriers include electrons and holes. Specifically, under the action of the driving voltage, the electrons and holes as carriers are injected from the cathode 3 and the anode 4 into the electron injection layer 6 and the hole injection layer 7, respectively, and the electrons and holes migrate to the light-emitting layer 1 through the electron transport layer and the hole transport layer, respectively, and meet and recombine in the light-emitting layer 1 to form excitons, and the excitons deactivate and release energy; and the released energy excites light-emitting molecules in the light-emitting layer 1, and the excited light-emitting molecules emit visible light after radiative relaxation.

According to the embodiment of the present application, the display panel is provided with the charge generation layer 2 between two adjacent light-emitting layers 1. In addition to the cathode 3 and the anode 4, the charge generation layer 2 may also generate holes and electrons, the holes and electrons are injected into the light-emitting layers 1 on two sides of the charge generation layer 2, respectively such that the number of excitons formed by recombination of the electrons and holes in the light-emitting layers 1 can be increased, thereby improving the light-emitting efficiency of an organic light-emitting diode.

It has been found through research that the turn-on voltage of the second light-emitting part 12 corresponding to the second charge generation part 22 can be increased by reducing the thickness of the second charge generation part 22, since after the thickness of the second charge generation part 22 is reduced, the energy band of the second charge generation part 22 is incompletely bent under the driving of the applied electric field, allowing the turn-on voltage of the second light-emitting part 12 to rise.

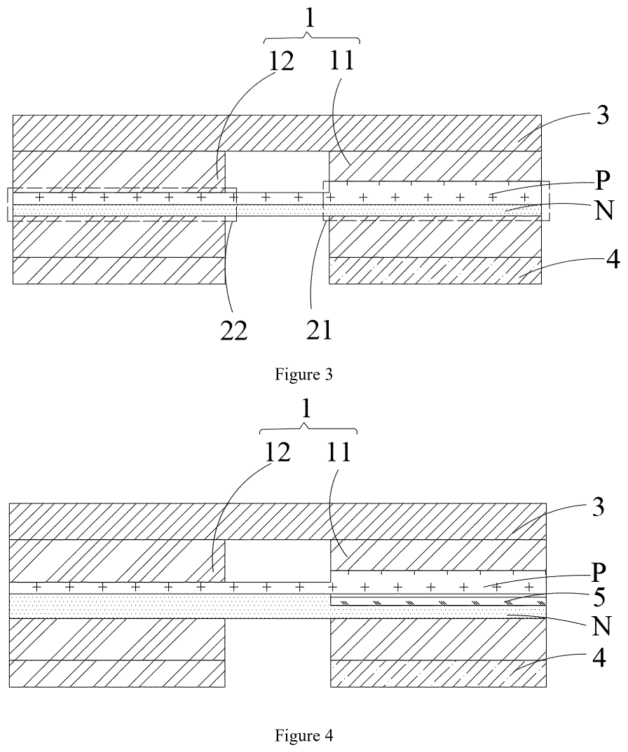

Referring to FIG. 3, in some optional embodiments, the charge generation layer 2 includes a P-type charge generation layer P and an N-type charge generation layer N stacked in the thickness direction of the display panel; and at least the P-type charge generation layer P of the first charge generation part 21 has a thickness greater than the thickness of the P-type charge generation layer P of the second charge generation part 22.

It should be noted that the charge generation layer 2 includes the P-type charge generation layer P and the N-type charge generation layer N; under the action of an applied reverse voltage, electrons of the P-type charge generation layer P migrate toward the N-type charge generation layer N, thereby generating more holes to migrate toward the light-emitting layer 1 adjacent thereto; and electrons of the N-type charge generation layer N migrate toward the light-emitting layer 1 adjacent thereto. A dipole formed by the charge generation layer 2 is divided into holes and electrons, which are injected into the light-emitting layers 1 on two sides through channels due to Zener breakdown, and are respectively recombined with the electrons and holes in the light-emitting layers 1 on two sides to form excitons, thereby enabling the light-emitting layers 1 to emit light.

It has been obtained through a plurality of experimental simulations, the change in the thickness of the P-type charge generation layer P have a greater effect on the change in the value of the turn-on voltage of the corresponding light-emitting part, and the change in the thickness of the N-type charge generation layer N have a smaller effect on the change in the value of the turn-on voltage of the corresponding light-emitting part.

Specifically, when the value of the thickness of the P-type charge generation layer P is controlled between 1 nm and 10 nm with other conditions kept constant, the turn-on voltage of the corresponding light-emitting part varies between 5.81 and 6.97 V, and a maximum difference in the turn-on voltage of the light-emitting part is 1.16 V (that is, the difference between 6.97 V and 5.81 V is 1.16 V). When the value of the thickness of the N-type charge generation layer N is controlled between 1 nm and 10 nm with other conditions kept constant, the variation difference in the turn-on voltage of the corresponding light-emitting part is about 0.01 V, which is a very small change.

Therefore, in the embodiment of the present application, at least the P-type charge generation layer P of the first charge generation part 21 has a thickness greater than the thickness of the P-type charge generation layer P of the second charge generation part 22, that is, the thickness of the P-type charge generation layer P of the second charge generation part 22 may be reduced, and/or the thickness of the P-type charge generation layer P of the first charge generation part 21 may be increased, such that the difference between the turn-on voltage of the second light-emitting part 12 and the driving voltage of the first light-emitting part 11 is reduced to avoid the problem of color mixture in which the second light-emitting part 12 is turned on at the same time as the first light-emitting part 11 is turned on. In order to ensure the electron transport effect of the P-type charge generation layer P, the thickness of the portion of the charge generation layer 2 that is adjacent to the P-type charge generation layer P of the first charge generation part 21 may be increased, and/or the thickness of the portion of the charge generation layer 2 that is adjacent to the P-type charge generation layer P of the second charge generation part 22 may be reduced, ensuring that the turn-on voltage can be efficiently adjusted.

A material of the P-type charge generation layer P may include a P-type inorganic semiconductor material, a P-type metal dopant, or a P-type organic semiconductor material. A material of the N-type charge generation layer N may include an N-type inorganic semiconductor material, an N-type metal dopant, or an N-type organic semiconductor material. In practice, there is no limitations on the selection of the dopant for each of the P-type charge generation layer P and the N-type charge generation layer N, and the P-type charge generation layer P and the N-type charge generation layer N may be made of the same type of material or different types of material, which is not limited specifically.

Optionally, the P-type charge generation layer P includes a P-type organic semiconductor material and a P-type metal dopant, and the P-type organic semiconductor material may include a quinone derivative including, but not limited to, tetracyanoquinodimethane (TCNQ) and 2,3,5,6-tetrafluoro-7,7′,8,8′-tetracyanoquinodimethane (F4-TCNQ). The P-type metal dopant may include a metal halide, such as CuI, AgI and BiI3.

The N-type charge generation layer N may include an N-type organic semiconductor material and an N-type metal dopant. The N-type organic semiconductor material may include an organic compound of triazine, and the N-type metal dopant may be some active metals, such as ytterbium (Yb) or lithium (Li).

In some optional embodiments, the thickness of the P-type charge generation layer P of the first charge generation part 21 ranges from 3 to 20 nm; and/or, the thickness of the P-type charge generation layer P of the second charge generation part 22 ranges from 1 to 3 nm.

It should be understood that the thickness of the P-type charge generation layer P of the first charge generation part 21 needs to be greater than the thickness of the P-type charge generation layer P of the second charge generation part 22. For example, when the thickness of the P-type charge generation layer P of the first charge generation part 21 is 3 nm, the thickness of the P-type charge generation layer P of the second charge generation part 22 needs to be less than 3 nm. Optionally, the thickness of the P-type charge generation layer P of the first charge generation part 21 is 10 nm, and the thickness of the P-type charge generation layer P of the second charge generation part 22 is 2 nm, ensuring that the turn-on voltage of the second light-emitting part 12 is increased relatively without affecting normal light-emitting display of the first light-emitting part 11 and the second light-emitting part 12.

It has been experimentally obtained that when the thickness of the P-type charge generation layer P of the second charge generation part 22 is 2 nm, the turn-on voltage of the second light-emitting part 12 corresponding thereto has an abrupt change. For example, when the thickness of the P-type charge generation layer P of the second charge generation part 22 is 4 nm and 5 nm, the turn-on voltage of the second light-emitting part 12 corresponding thereto is 5.85 V. When the thickness of the P-type charge generation layer P of the second charge generation part 22 is 3 nm, the turn-on voltage of the second light-emitting part 12 corresponding thereto is 5.86 V. When the thickness of the P-type charge generation layer P of the second charge generation part 22 is 2 nm, the turn-on voltage of the second light-emitting part 12 corresponding thereto is 6.97 V, with a difference of 1.11 V (i.e., the difference between the turn-on voltage of 5.86 V of the second light-emitting part 12 corresponding to the thickness of 3 nm of the P-type charge generation layer P and the turn-on voltage of 6.97 V of the second light-emitting part 12 corresponding to the thickness of 2 nm of the P-type charge generation layer P). Accordingly, the thickness of the P-type charge generation layer P of the second charge generation part 22 may be set to 2 nm to ensure the effect of increasing the turn-on voltage of the second light-emitting part 12 corresponding thereto.

It should be understood that reducing the difference between the turn-on voltage of the second light-emitting part 12 and the driving voltage of the first light-emitting part 11 may be achieved by reducing the driving voltage of the first light-emitting part 11, in addition to relatively increasing the turn-on voltage of the second light-emitting part 12.

Referring to FIG. 4, in some optional embodiments, the display panel further includes an organic layer 5, where the organic layer 5 is disposed between the P-type charge generation layer P and the N-type charge generation layer N; and in the thickness direction of the display panel, an orthographic projection of the organic layer 5 on the charge generation layer 2 covers an orthographic projection of the first light-emitting part 11 on the charge generation layer 2.

It should be noted that the inventors have found through research that when the organic layer 5 is disposed between the P-type charge generation layer P and the N-type charge generation layer N corresponding to the first light-emitting part 11, electrons may tunnel from the P-type charge generation layer P toward the N-type charge generation layer N without having to overcome the energy barrier, and the current density of the first light-emitting part 11 is significantly increased at the same voltage, that is, the electron mobility is increased, so that the driving voltage of the first light-emitting part 11 is reduced.

For example, as the thickness of the P-type charge generation layer P corresponding to the first light-emitting part 11 is 2 nm and the thickness of the N-type charge generation layer N is 5 nm, when the organic layer 5 with a thickness of 1 nm is disposed between the P-type charge generation layer P and the N-type charge generation layer N corresponding to the first light-emitting part 11, the driving voltage of the first light-emitting part 11 is reduced from 8.26 V to 7.41 V as compared to the driving voltage of the first light-emitting part without the organic layer 5, thus significantly reducing the driving voltage.

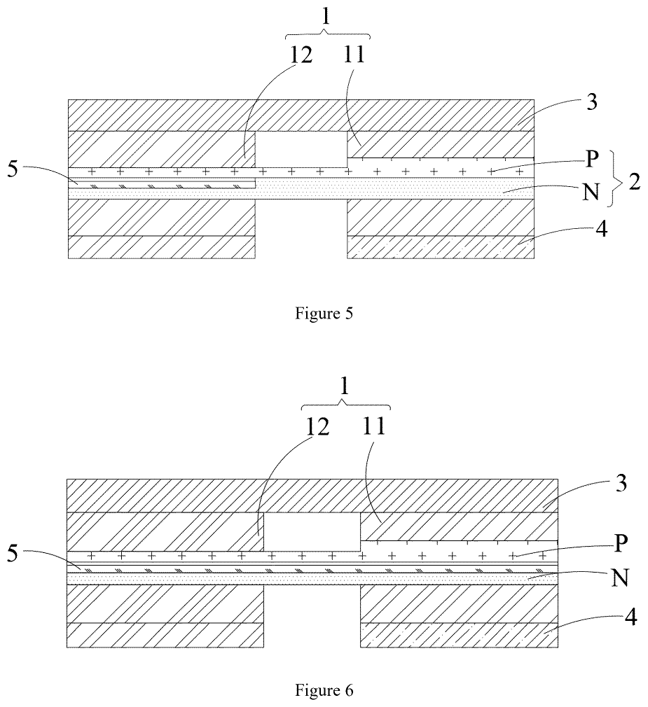

Moreover, the applicant has also found that when the turn-on voltage of the second light-emitting part 12 is relatively increased by reducing the thickness of the P-type charge generation layer P of the second charge generation part 22, the driving voltage of the second light-emitting part 12 also increases, which affects the normal light-emitting display of the second light-emitting part 12. Therefore, in order to reduce the driving voltage of the second light-emitting part 12, it is also possible to provide the organic layer 5 between the P-type charge generation layer P and the N-type charge generation layer N corresponding to the second light-emitting part 12. Specifically, referring to FIG. 5, in the thickness direction of the display panel, an orthographic projection of the organic layer 5 on the charge generation layer 2 covers an orthographic projection of the second light-emitting part 12 on the charge generation layer 2. The organic layer 5 is provided to solve the problem of the increase in the driving voltage of the second light-emitting part 12 caused by the reduction in the thickness of the P-type charge generation layer P of the second charge generation part 22.

It should be noted that the organic layer 5 may be disposed only between the P-type charge generation layer P and the N-type charge generation layer N corresponding to the first light-emitting part 11, or only between the P-type charge generation layer P and the N-type charge generation layer N corresponding to the second light-emitting part 12. That is, the organic layer 5 is patterned, or is formed correspondingly by Fine Metal Mask (FMM). Of course, in order to simplify the production process and reduce production costs and referring to FIG. 6, it is also possible to provide the organic layer 5 between the P-type charge generation layer P and the N-type charge generation layer N corresponding to each of the first light-emitting part 11 and the second light-emitting part 12, that is, the organic layer 5 may be provided as an entire layer covering the entire N-type charge generation layer N.

It should be understood that in some other optional embodiments, it is also possible to provide the organic layer 5 between the P-type charge generation layer P and the N-type charge generation layer N corresponding to the first light-emitting part 11, and the thickness of the P-type charge generation layer P corresponding to the first light-emitting part 11 is the same as the thickness of the P-type charge generation layer P corresponding to the second light-emitting part 12; moreover, the thickness of the N-type charge generation layer N corresponding to the first light-emitting part 11 is the same as the thickness of the N-type charge generation layer N corresponding to the second light-emitting part 12. That is, by reducing the driving voltage of the first light-emitting part 11, the difference between the turn-on voltage of the second light-emitting part 12 and the driving voltage of the first light-emitting part 11 is reduced to avoid the problem of color mixture.

In some optional embodiments, the organic layer 5 is made of the same material as one of the P-type charge generation layer P and the N-type charge generation layer N.

It should be understood that the organic layer 5 may be formed by the same process as the organic portion of one of the P-type charge generation layer P and the N-type charge generation layer N, to reduce production costs; and the driving voltage of the first light-emitting part 11 and/or the second light-emitting part 12 corresponding to the organic layer 5 is reduced slightly, which may suppress the voltage drift, without affecting the efficiency. Specifically, when the N-type charge generation layer N includes an N-type organic semiconductor material and an N-type metal dopant, the N-type organic semiconductor material and the N-type metal dopant are simultaneously deposited on the light-emitting layer 1 and are mutually doped to form the N-type charge generation layer N; after the N-type charge generation layer N is formed, a control switch of the N-type metal dopant is turned off, and only the N-type organic semiconductor material is controlled to continue to be deposited on the N-type charge generation layer N, that is, the N-type organic semiconductor material is used as the organic layer 5. This process method may effectively simplify the production process and reduce costs.

Optionally, a material of the organic layer 5 includes at least one of a phenyl-containing compound, a carbazole-containing compound, a triazine-containing compound, and a phenanthroline-containing compound.

Specifically, the material of the organic layer 5 may include at least one of N-(1,1′-diphenyl-2-yl)-N-(9,9-dimethyl-fluoren-2-yl)-9,9′-spirofluoren-2-yl-amine; N4,N4-bis([1,1′-biphenyl]-4-yl)-N4′-([1,1′:4′,1″-terphenyl]-4-yl)-N4′-phenyl-[1,1′-biphenyl]-4,4′-diamine; 5-(4-(4,6-diphenyl-1,3,5-triazin-2-yl)dibenzo[b,d]thiophen-2-yl)-7,7-dimethyl-5,7-dihydroindeno[2,1-b]carbazole; 2,9-bis(naphthalen-2-yl)-4,7-diphenyl-1,10-phenanthroline; and 4,7-diphenyl-1,10-phenanthroline 1,3,5-tris(1-phenyl-1H-benzimidazol-2-ylphenyl).

In some optional embodiments, in the thickness direction of the display panel, the organic layer 5 has a thickness less than or equal to the thickness of each of the P-type charge generation layer P and the N-type charge generation layer N, that is, the thickness of the organic layer 5 is less than or equal to the thickness of the P-type charge generation layer and the thickness of the organic layer 5 is also less than or equal to the thickness of the N-type charge generation layer N. It should be understood that the thickness of the organic layer 5 shall not be too large, which otherwise affects the overall thickness of the display panel, and may result in an excessively large change in the driving voltage of the corresponding light-emitting part, thus affecting its normal operation. Optionally, the thickness of the organic layer 5 ranges from 1 nm to 2 nm. For example, the thickness of the organic layer 5 may be 1 nm, 1.5 nm or 2 nm.

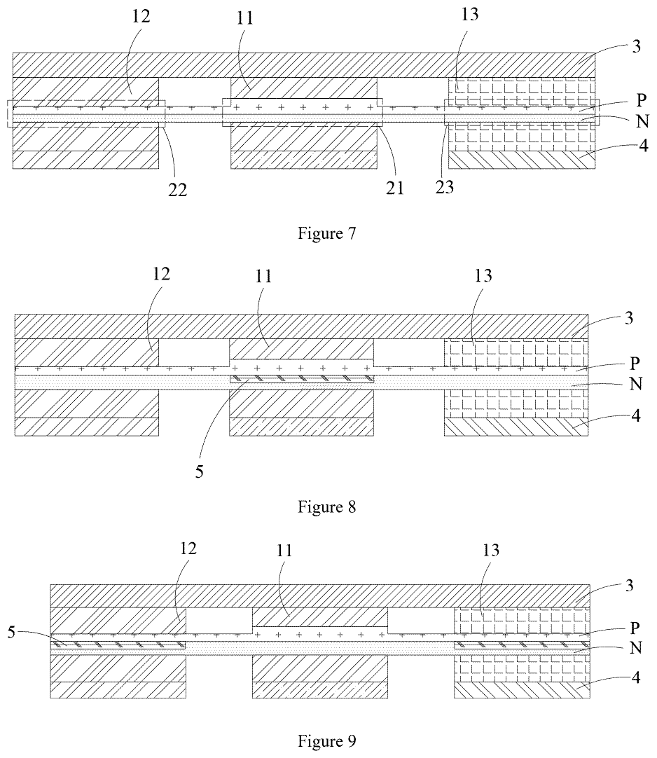

Referring to FIGS. 7 to 10, in some optional embodiments, the light-emitting layer 1 further includes a third light-emitting part 13, and the third light-emitting part 13 is disposed adjacent to the first light-emitting part 11; the charge generation layer 2 further includes a third charge generation part 23, and in the thickness direction of the display panel, an orthographic projection of the third charge generation part 23 on the light-emitting layer 1 covers the third light-emitting part 13, and the thickness of the first charge generation part 21 is greater than a thickness of the third charge generation part 23.

It should be understood that the second light-emitting part 12 and the third light-emitting part 13 are both disposed adjacent to the first light-emitting part 11, in order to avoid the problem of color mixture in which both the second light-emitting part 12 and the third light-emitting parts 13 are turned on due to current crosstalk at the same time as the first light-emitting part 11 is turned on. In this embodiment, the thickness of the first charge generation part 21 is greater than the thickness of the third charge generation part 23, that is, the thickness of the third charge generation part 23 may be reduced or the thickness of the first charge generation part 21 may be increased, such that a turn-on voltage of the third light-emitting part 13 is increased relatively, thereby reducing the difference between the turn-on voltage of the third light-emitting part 13 and the driving voltage of the first light-emitting part 11, preventing current crosstalk between the first light-emitting part 11 and the third light-emitting part 13, and avoiding the problem of color mixture in which the third light-emitting part 13 is turned on at the same time as the first light-emitting part 11 is turned on.

Optionally, the thickness of the third charge generation part 23 is equal to the thickness of the second charge generation part 22. That is, the P-type charge generation layer P and the N-type charge generation layer N of the third charge generation part 23 may respectively have the same thickness as the P-type charge generation layer P and the N-type charge generation layer N of the second charge generation part 22, thus facilitating the preparation.

It should be noted that the first light-emitting part 11, the second light-emitting part 12 and the third light-emitting part 13 are light-emitting parts having different light-emitting colors. For example, the first light-emitting part 11, the second light-emitting part 12 and the third light-emitting part 13 are one of a red light-emitting part, a green light-emitting part, and a blue light-emitting part, respectively, so that the color display of the display panel is achieved by the red, green, and blue light emitted from the red, green, and blue light-emitting parts.

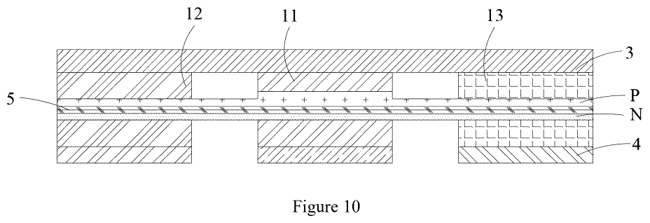

As shown in FIG. 8, when three light-emitting parts are provided, the organic layer 5 may also be disposed only between the P-type charge generation layer P and the N-type charge generation layer N corresponding to the first light-emitting part 11 to reduce the driving voltage of the first light-emitting part 11. Alternatively, as shown in FIG. 9, the organic layer 5 may also be disposed only between the P-type charge generation layer P and the N-type charge generation layer N corresponding to each of the second light-emitting part 12 and the third light-emitting part 13 to solve the problem of the increase in the driving voltage of the second and third light-emitting parts 12 and 13 caused by the reduction in the thickness of the P-type charge generation layer P of each of the second charge generation part 22 and the third charge generation part 23. As shown in FIG. 10, the organic layer 5 may also be provided as an entire layer, which is easy to form and reduces production costs. Alternatively, the organic layer 5 is provided between the P-type charge generation layer P and the N-type charge generation layer N corresponding to each of the first light-emitting part 11, the second light-emitting part 12 and the third light-emitting part 13 by means of patterning.

It has been found through research that the color mixture phenomenon of the three-color light-emitting parts, i.e., the red light-emitting part, the green light-emitting part, and the blue light-emitting part occurs when the red light-emitting part or the green light-emitting part is turned on at the same time as the blue light-emitting part is turned on. Therefore, optionally, the first light-emitting part 11 is the blue light-emitting part, and the second light-emitting part 12 and the third light-emitting part 13 may be one of the red light-emitting part and the green light-emitting part, respectively.

The thickness of the first charge generation part 21 corresponding to the blue light-emitting part is greater than the thickness of the second charge generation part 22 and the thickness of the third charge generation part 23 such that the difference between the driving voltage of the blue light-emitting part and the turn-on voltage of the red light-emitting part and the green light-emitting part is reduced, thereby avoiding the situation in which the red light-emitting part and the green light-emitting part are turned on due to current crosstalk at the same time as the blue light-emitting part is turned on.

An embodiment of the present application further provides a display device, including a display panel of any one of the above embodiments.

Accordingly, the display device provided in the embodiment of the present application has the technical effect of the technical solution of the display panel in any one of the above embodiments, and the structure and the explanation of terms that are the same as or corresponding to the above embodiments will not be repeated herein.

The display device provided in the embodiment of the present application may be applied to a smart phone, or any electronic product with a display function, including, but not limited to: a TV set, a notebook computer, a desktop monitor, a tablet computer, a digital camera, a smart bracelet, smart glasses, a vehicle-mounted display, a medical apparatus, an industrial control apparatus, a touch interaction terminal, etc., which is not specifically limited in the embodiments of the present application.

The foregoing descriptions are merely specific embodiments of the present application. A person skilled in the art may clearly understand that, for ease and brevity of description, the specific working processes of the system, module, and component described above can refer to the corresponding processes in the foregoing method embodiments and will not be described herein. It should be understood that the scope of protection of the present application is not limited thereto, any equivalent modification or replacement that can be easily conceived within the technical scope disclosed in the present application by any person skilled in the art shall fall within the scope of protection of the present application.

It should also be noted that the exemplary embodiments mentioned in the present application describe some methods or systems based on a series of steps or devices. However, the present application is not limited to the order of the foregoing steps. That is, the steps may be performed in the order mentioned in the embodiments, or may be performed in an order different from that in the embodiments, or several steps may be performed at the same time.

What is claimed is:

1. A display panel, comprising:
at least two light-emitting layers stacked in a thickness direction of the display panel, wherein a charge generation layer is provided between two adjacent light-emitting layers, and comprises a first charge generation part and a second charge generation part; and
in a direction perpendicular to the thickness direction of the display panel, each light-emitting layer comprises a first light-emitting part and a second light-emitting part spaced apart from each other, and in the thickness direction of the display panel, an orthographic projection of the first charge generation part on the light-emitting layer covers the first light-emitting part, an orthographic projection of the second charge generation part on the light-emitting layer covers the second light-emitting part, and the first charge generation part has a thickness greater than a thickness of the second charge generation part.

2. The display panel according to claim 1, wherein each of the first charge generation part and the second charge generation part of the charge generation layer comprises a P-type charge generation layer and an N-type charge generation layer stacked in the thickness direction of the display panel; and
the P-type charge generation layer of the first charge generation part has a thickness greater than the thickness of the P-type charge generation layer of the second charge generation part.

3. The display panel according to claim 2, wherein the thickness of the P-type charge generation layer of the first charge generation part ranges from 3 to 20 nm.

4. The display panel according to claim 2, wherein the thickness of the P-type charge generation layer of the second charge generation part ranges from 1 to 3 nm.

5. The display panel according to claim 2, further comprising an organic layer, wherein the organic layer is disposed between the P-type charge generation layer and the N-type charge generation layer; and
in the thickness direction of the display panel, an orthographic projection of the organic layer on the charge generation layer covers an orthographic projection of the first light-emitting part on the charge generation layer.

6. The display panel according to claim 2,, further comprising an organic layer, wherein the organic layer is disposed between the P-type charge generation layer and the N-type charge generation layer; and
in the thickness direction of the display panel, the orthographic projection of the organic layer on the charge generation layer covers an orthographic projection of the second light-emitting part on the charge generation layer.

7. The display panel according to claim 2, further comprising an organic layer, wherein the organic layer is disposed between the P-type charge generation layer and the N-type charge generation layer; and
in the thickness direction of the display panel, an orthographic projection of the organic layer on the charge generation layer covers an orthographic projection of the first light-emitting part on the charge generation layer and an orthographic projection of the second light-emitting part on the charge generation layer.

8. The display panel according to claim 5, wherein the organic layer is made of the same material as one of the P-type charge generation layer and the N-type charge generation layer.

9. The display panel according to claim 5, wherein in the thickness direction of the display panel, the organic layer has a thickness less than or equal to the thickness of each of the P-type charge generation layer and the N-type charge generation layer.

10. The display panel according to claim 5, wherein the thickness of the organic layer ranges from 1 to 2 nm.

11. The display panel according to claim 5, wherein a material of the organic layer comprises at least one of a phenyl-containing compound, a carbazole-containing compound, a triazine-containing compound, and a phenanthroline-containing compound.

12. The display panel according to claim 1, wherein the light-emitting layer further comprises a third light-emitting part disposed adjacent to the first light-emitting part, the charge generation layer further comprises a third charge generation part, and in the thickness direction of the display panel, an orthographic projection of the third charge generation part on the light-emitting layer covers the third light-emitting part, and the thickness of the first charge generation part is greater than a thickness of the third charge generation part.

13. The display panel according to claim 12, wherein the thickness of the third charge generation part is equal to the thickness of the second charge generation part.

14. The display panel according to claim 12, wherein the first light-emitting part, the second light-emitting part, and the third light-emitting part are one of a red light-emitting part, a green light-emitting part, and a blue light-emitting part, respectively.

15. The display panel according to claim 14, wherein the first light-emitting part is the blue light-emitting part, and the second light-emitting part and the third light-emitting part are one of the red light-emitting part and the green light-emitting part, respectively.

16. A display device, comprising a display panel according to claim 1.
